(19) United States
(12) Patent Application Publication
(10) Pub. No.: US 2004/0126914 A1
(43) Pub. Date: Jul. 1, 2004

(54) Method of forming a thin film transistor and method of forming the thin film transistor on a color filter

(75) Inventors: Jiun-Jye Chang, Kaohsiung (TW); Chih-Chiang Chen, Ilan (TW); Ching-Sang Chuang, Hsinchu (TW)

Correspondence Address: Quintero Law Office, 3rd Floor, 1617 Broadway, Santa Monica, CA, 90404, US

(73) Assignee: Industrial Technology Research Institute

(21) Appl. No.: 10/603,542

(22) Filed: Jun. 25, 2003

(30) Foreign Application Priority Data
Dec. 17, 2002 (TW) 91136408

(51) Int. Cl. H01L 21/00; H01L 21/84

(52) U.S. Cl. 438/30; 438/163

(57) ABSTRACT

A method of forming a TFT and a method of forming the TFT on a color filter. With a first reticle, a metal layer and a hole exposing a substrate are defined. A color filter is formed in the hole. With a second reticle, a silicon island is defined above the color filter. With a third reticle, a photoresist layer is formed, and a gate and a gate oxide layer are defined. The photoresist layer is wider than the gate and the gate oxide layer, but narrower than the semiconductor island. Using the photoresist layer as a mask, a source/drain region is formed in the silicon island by implantation. The photoresist layer is then removed. Using the gate as a mask, a LDD region is formed in the silicon island by implantation. With a fourth reticle, a transparent electrode is defined. Thus, a TFT is formed on the color filter.

### BACKGROUND OF THE INVENTION

1. Field of the Invention

The present invention relates to a liquid crystal display process, and more particularly, to a method of forming a thin film transistor (TFT) and a method of forming the TFT on a color filter.

2. Description of the Related Art

A liquid crystal display (LCD) of an active matrix system using a thin film transistor (TFT) has become attractive as a high quality display apparatus. In order to display a color image in the LCD, it is necessary to provide color filters of red, green and blue (RGB) serving as the three primary colors.

In recent years, in order to increase the aperture ratio, a structure in which the color filters are formed on the side of the substrate on which the pixel driving elements reside (for example, the TFTs) has been proposed. The process for forming the structure is called a COA (color filter on array) process.

FIGS. 1A˜1C are an example of previously proposed COA processes. In FIG. 1A, in a first photolithography procedure, a semiconductor island 101 is defined on a substrate 100. In a second photolithography procedure, a source/drain region 102 is defined in the semiconductor island 101. In a third photolithography procedure, a gate 103 is defined above the semiconductor island 101 and a LDD (lightly doped drain) region 104 is defined in the semiconductor island 101. Thus, a TFT structure 110 having the LDD region 104 is formed on the substrate 100.

In FIG. 1A, in a fourth photolithography procedure, a source electrode 145 and a drain electrode 140 are defined to connect the source/drain region 102. Then, a first planarzation layer 120 is formed on the TFT structure 110 by deposition. In a fifth photolithography procedure, a contact window 130 through the first planarization layer 120 is formed to expose the drain electrode 140. In a sixth photolithography procedure, a transparent pixel electrode 150 is formed on part of the first planarzation layer 120 and in the contact window 130 to electrically connect the drain electrode 140.

In FIG. 1B, a second planarzation layer 160 is formed on the pixel electrode 150 by deposition.

In FIG. 1C, a color filter 170 is formed on the second planarzation layer 160 by, for example, a pigment dispersion method with some photolithography procedures.

The COA process of the prior art requires at least seven photolithography procedures. Thus, the conventional method is complicated and expensive.

### SUMMARY OF THE INVENTION

The object of the present invention is to provide a method of forming a thin film transistor (TFT) device on a substrate.

Another object of the present invention is to provide a method of forming a TFT device on a color filter, only requiring four reticles (or photomasks).

In order to achieve these objects, the present invention provides a method of forming a thin film transistor (TFT) device on a substrate. A photolithography process using a first reticle is performed, and a semiconductor island is formed on the substrate. An oxide layer is formed on the semiconductor island. A metal layer is formed on the oxide layer. A photolithography process using a second reticle is performed, and a photoresist pattern is formed on part of the metal layer. Using the photoresist pattern as a mask, part of the metal layer and part of the oxide layer are isotropically etched to form a gate and a gate dielectric layer. The photoresist pattern is wider than the gate and the gate dielectric layer, but narrower than the semiconductor island. Using the photoresist pattern as a mask, a heavy doping ion implantation is performed on the semiconductor island to form a source/drain region in part of the semiconductor island. The photoresist pattern is removed. Using the gate as a mask, a light doping ion implantation is performed on the semiconductor island to form a lightly doped drain (LDD) region in part of the semiconductor island.

The present invention also provides a method of forming thin film transistor (TFT) device on a color filter. A substrate having a predetermined light-transmitting area and a predetermined capacitor area is provided, wherein the light-transmitting area further includes an active area. A first metal layer is formed on the substrate. A photolithography process using a first reticle is performed, and part of the first metal layer is removed to form a hole exposing the substrate in the light-transmitting area, wherein the first metal layer in the capacitor area serves as a lower electrode of a capacitor. Pigment is filled into the hole to form a color filter on the substrate. A first buffer layer is formed on the color filter and the metal layer. A photolithography process using a second reticle is performed, and a semiconductor island is formed on the first buffer layer in the active area. An oxide layer is formed on the semiconductor island. A second metal layer is formed on the oxide layer. A photolithography process using a third reticle is performed, and a photoresist pattern is formed on part of the second metal layer. Using the photoresist pattern as a mask, part of the second metal layer, part of the oxide layer and part of the first buffer layer are isotropically etched to expose part of the color filter and part of the first metal layer. Thus, agate, a gate dielectric layer, an upper electrode of the capacitor and a dielectric layer of the capacitor are formed, wherein the photoresist pattern is wider than the gate and the gate dielectric layer, but narrower than the semiconductor island. Using the photoresist pattern as a mask, a heavy doping ion implantation is performed on the semiconductor island to form a source/drain region in part of the semiconductor island. The photoresist pattern is removed. Using the gate as a mask, a light doping ion implantation is performed on the semiconductor island to form a lightly doped drain (LDD) region in part of the semiconductor island. A photolithography process using a fourth reticle is performed, and a transparent conducting layer is formed on the color filter, wherein the transparent conducting layer electrically connects the source/drain region and the first metal layer.

### BRIEF DESCRIPTION OF THE DRAWINGS

The present invention can be more fully understood by reading the subsequent detailed description in conjunction with the examples and references made to the accompanying drawings, wherein:

FIGS. 1A˜1C are sectional views of a COA process of the prior art;

FIGS. 2A˜2D are sectional views of a fabrication process for a TFT device according to the present invention; and

FIGS. 3A˜3G are sectional views of a fabrication process of forming a TFT device on a color filter according to the present invention.

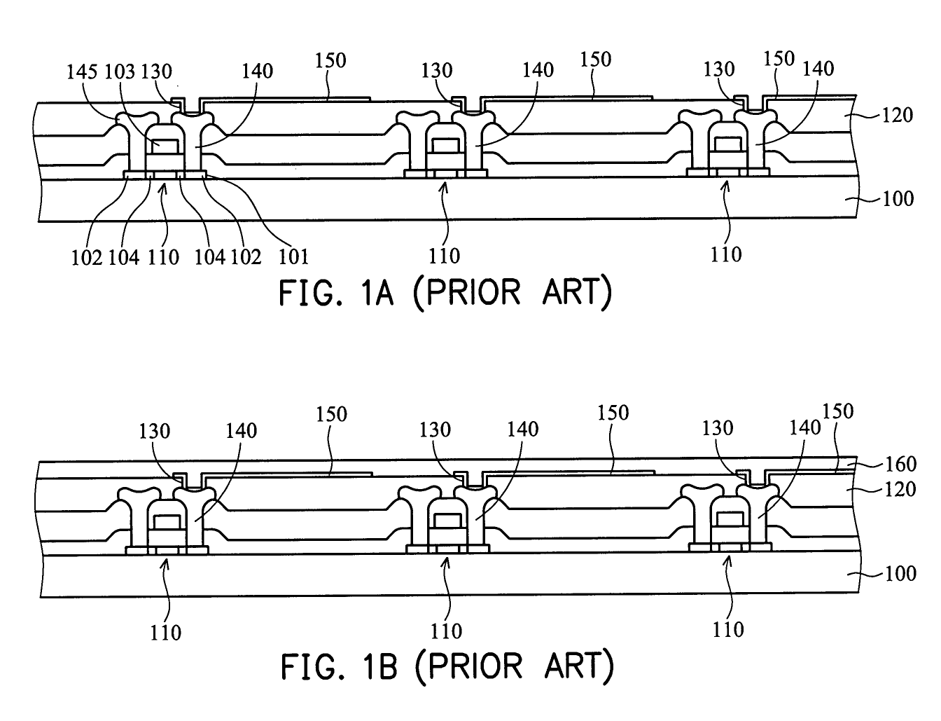

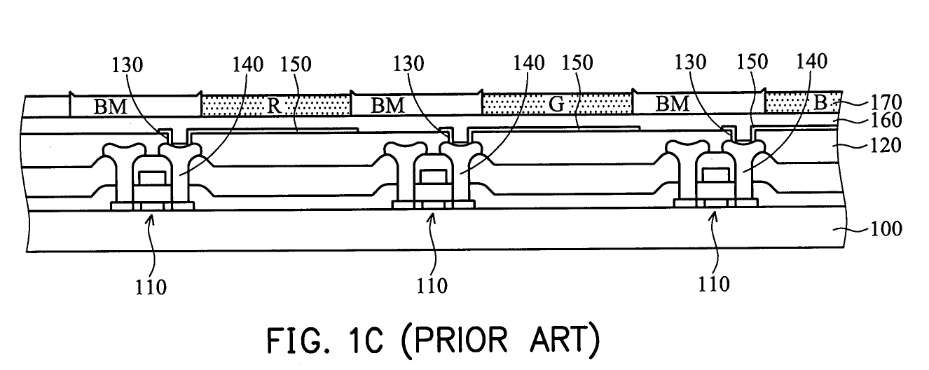

### DETAILED DESCRIPTION OF THE INVENTION

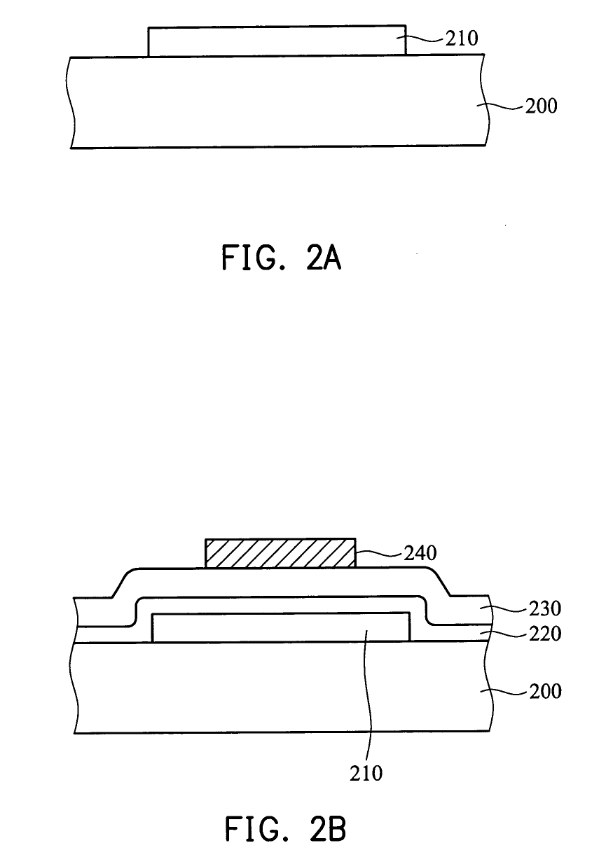

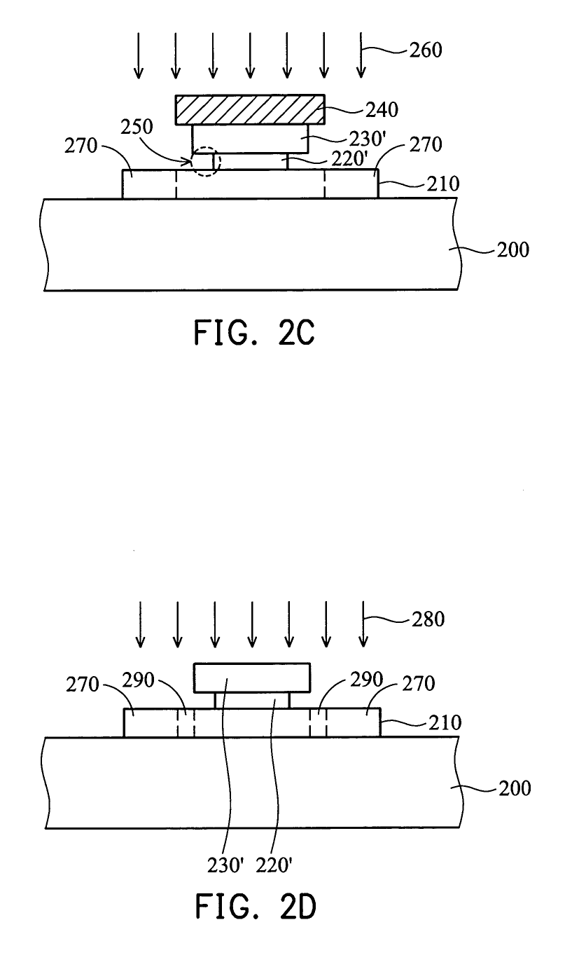

FIGS. 2A˜2D are sectional views of a fabrication process for a TFT device according to the present invention.

In FIG. 2A, an insulating substrate 200, such as glass, is provided. A semiconductor layer (not shown), such as polysilicon, is formed on the insulating substrate 200 by deposition. A photolithography process using a first reticle is then performed, and the semiconductor layer (not shown) is patterned to form a semiconductor island 210 on the insulating substrate 200.

In FIG. 2B, a conformal oxide layer 220, such as SiO₂, is formed on the semiconductor island 210 by, for example, deposition. Then, a conformal metal layer 230, such as Al, Ti, Ta, Cr, Mo, MoW or alloy of the above metals, is formed on the oxide layer 220 by, for example, sputtering. A photolithography process using a second reticle is then performed, and a photoresist pattern 240 is formed on part of the metal layer 230. The photoresist pattern 240 is located above part of the semiconductor island 210.

In FIG. 2C, using the photoresist pattern 240 as a mask, part of the metal layer 230 and part of the oxide layer 220 are isotropically etched to form a gate 230′ and a gate dielectric layer 220′, wherein the isotropic etching can be wet etching. It should be noted that the width of the photoresist pattern 240, as shown in FIG. 2C, is wider than the gate 230′ and the gate dielectric layer 220′, but narrower than the semiconductor island 210.

Two examples for illustrating the above wet etching follows, but are not intended to limit the present invention. One example is a two-step etching process. For example, a Ti or Al layer serves as the metal layer 230, and a SiO₂ layer serves as the oxide layer 220. A first etchant (mainly including phosphoric acid, acetic acid and nitric acid; additionally, a small amount about 0˜1 vol % of hydrofluoric acid can be added) with a first etching rate used to remove part of the metal layer 230. Then, a second etchant (hydrofluoric acid, or mainly including phosphoric acid, acetic acid, nitric acid and hydrofluoric acid) with a second etching rate is used to remove part of the oxide layer 220. It should be noted that the second etching rate is greater than the first etching rate, whereby the width of the gate dielectric layer 220′ is narrower than that of the gate 230′. Thus, a cavity 250 is formed at either side of the gate dielectric layer 220′. The cavity 250 can decrease gate leakage.

Another example is a direct etching process. For example, a Ti layer serves as the metal layer 230, and a SiO₂ layer serves as the oxide layer 220. An etchant (mainly including phosphoric acid, acetic acid, nitric acid and about 5-1 vol. % of hydrofluoric acid, and gradually decreasing HF concentration in the etching process) is used to remove part of the metal layer 230 and part of the oxide layer 220. The different HF concentration causes different etching rates between Ti and SiO₂ (the etching rate of SiO₂ is greater than that of Ti). Thus, a cavity 250 is formed at either side of the gate dielectric layer 220′. The cavity 250 can decrease gate leakage.

In FIG. 2C, using the photoresist pattern 240 as a mask, a heavy doping ion implantation 260, such as n⁺-type ions implantation, is performed on the semiconductor island 210 to form a self-aligned source/drain region 270 in part of the semiconductor island 210.

In FIG. 2C, the photoresist pattern 240 is removed. Using the gate 230′ as a mask, a light doping ion implantation 280 such as n⁻-type ions implantation is performed on the semiconductor island 210 to form a self-aligned lightly doped drain (LDD) region 290 in part of the semiconductor island 210. According to the present invention, a TFT structure having LDD is obtained with only two photolithography processes.

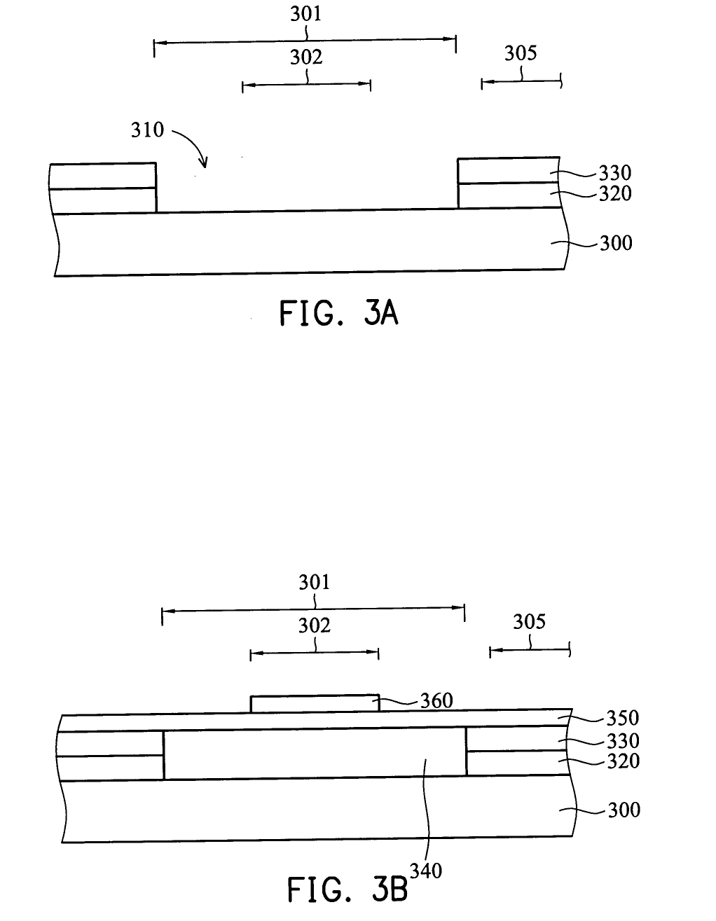

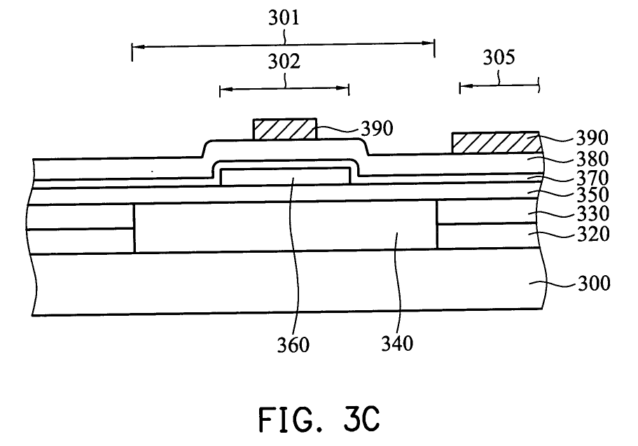

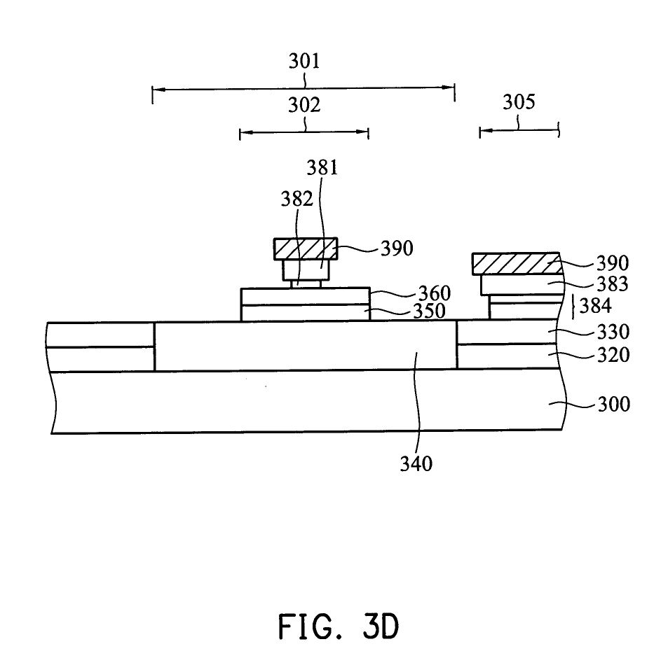

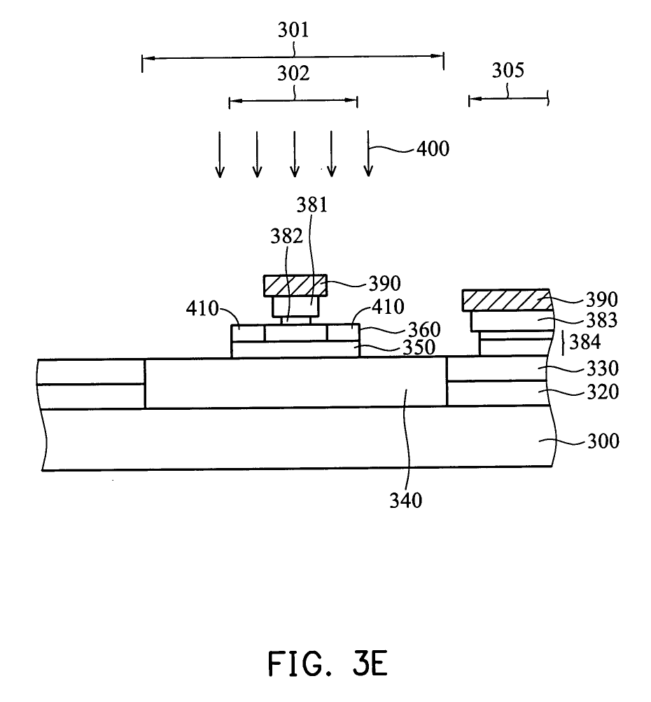

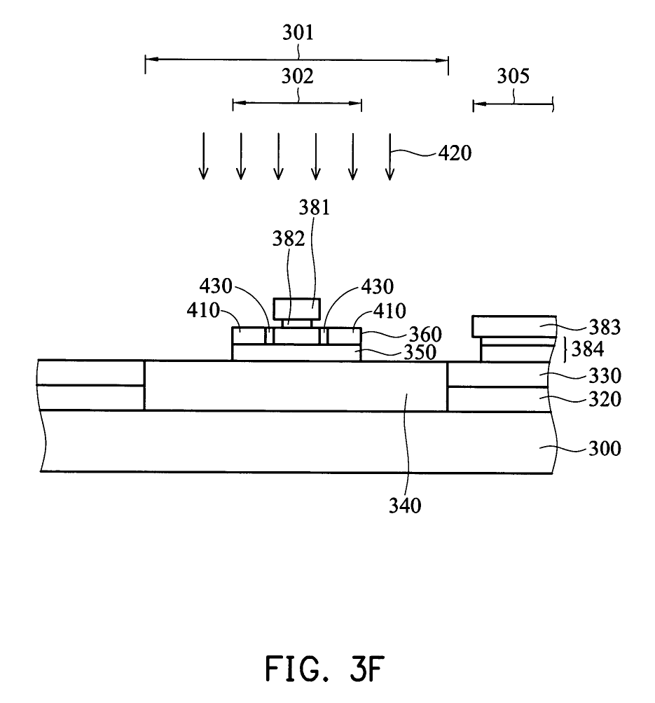

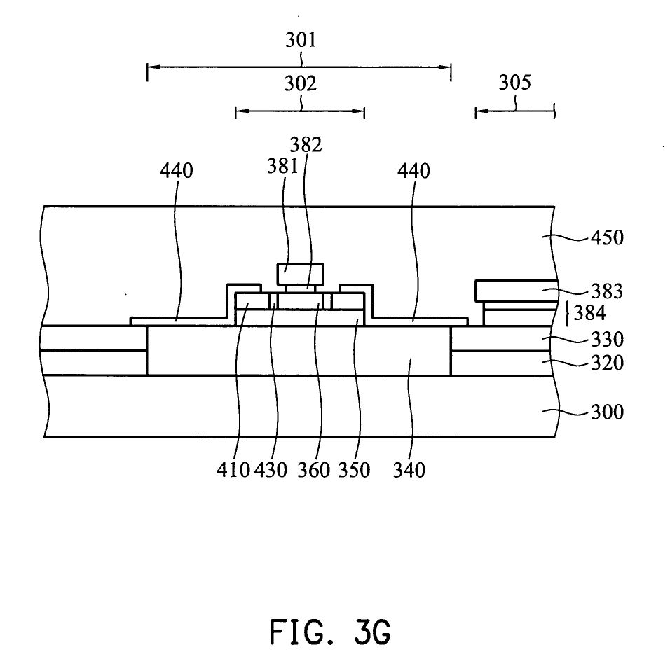

The TFT manufacturing method of the present invention is suitable for an LCD process, thereby simplifying the conventional process. FIGS. 3A-3G illustrate a fabrication process of forming a TFT device on a color filter according to the present invention.

In FIG. 3A, an insulating substrate 300, such as glass, having a predetermined light-transmitting area 301 and a predetermined capacitor area 305 is provided, wherein the light-transmitting area 301 further includes an active area 302. A first buffer layer (not shown) can be formed on the substrate 300. The first buffer layer (not shown) can be SiO₂. Then, a metal layer (not shown) is formed on the buffer layer (not shown) by, for example, sputtering. The metal layer (not shown) can be Al. A photolithography procedure using a first reticle is then performed, and part of the metal layer (not shown) and part of the first buffer layer (not shown) are removed to form an opening 310 exposing the substrate 300 in the light-transmitting area 301. Thus, a remaining first buffer layer 320 and a remaining first metal layer 330 are formed on part of the substrate 300. The remaining first metal layer 330 serves as a lower electrode of a capacitor in the capacitor area 305.

In FIG. 3B, using an inkjet method, at least one color pigment (also called color resist) is filled into the opening 310 to form a color filter 340 on the substrate 300 by, for example, nozzle(s). The colors of the color pigment can include red, green and blue. It should be noted that the thickness of the color filter 340 can be equal or unequal to the total thickness of the first buffer layer 320 plus the first metal layer 330. In addition, when the total thickness of the first buffer layer 320 plus the first metal layer 330 is fixed, the conductivity of the first metal layer 330 can be increased by decreasing the thickness of the buffer layer 320 or without forming the buffer layer 320.

In FIG. 3B, a second buffer layer 350, such as SiO₂, is formed on the color filter 340 and the first metal layer 330. The second buffer layer 350 serves as a planarization layer and protects the color filter 340 from damage. Then, a semiconductor layer (not shown), such as polysilicon, is formed on the second buffer layer 350 by, for example, deposition. A photolithography procedure using a second reticle is then performed, and the semiconductor layer (not shown) is patterned to form a semiconductor island 360 on the second buffer layer 350 in the active area 302.

In FIG. 3C, a conformal oxide layer 370, such as SiO₂, is formed on the second buffer layer 350 and the semiconductor island 360 by, for example, deposition. Then, a conformal metal layer 380, such as Al, Ti, Ta, Cr, Mo, MoW or alloy of the above, is formed on the oxide layer 370 by, for example, sputtering. A photolithography using a third reticle is then performed, and a photoresist pattern 390 is formed on part of the metal layer 380 in the capacitor area 305 and part of the active area 302.

In FIG. 3D, using the photoresist pattern 390 as a mask, part of the second metal layer 380, part of the oxide layer 370 and part of the second buffer layer 350 are isotropically etched to expose a partial surface of the color filter 340 and the first metal layer 330, thereby forming a gate 381, a gate dielectric layer 382, an upper electrode 383 and a dielectric layer 384 of the capacitor. The isotropic etching can be wet etching. It should be noted that the width of the photoresist pattern 390 in the active area 302, as shown in FIG. 3D, is greater than the gate 381 and the gate dielectric layer 382, but narrower than the semiconductor island 360.

Two examples for illustrating the above wet etching follows, but are not intended to limit the present invention. One example is a two-step etching process. For example, a Ti or Al layer serves as the second metal layer 380, and a SiO₂ layer serves as the oxide layer 370. A first etchant (mainly including phosphoric acid, acetic acid and nitric acid, additionally, a small amount about 0˜1 vol. % of hydrofluoric acid can be added) with a first etching rate is used to remove part of the second metal layer 380. Then, a second etchant (hydrofluoric acid, or mainly including phosphoric acid, acetic acid, nitric acid and hydrofluoric acid) with a second etching rate is used to remove part of the oxide layer 370. It should be noted that the second etching rate is greater than the first etching rate, whereby the width of the gate dielectric layer 382 is narrower than that of the gate 381. Thus, a cavity is formed at either side of the gate dielectric layer 382. The cavity can decrease gate leakage.

Another example is a direct etching process. For example, a Ti layer serves as the second metal layer 380, and a SiO₂ layer serves as the oxide layer 370. An etchant (mainly including phosphoric acid, acetic acid, nitric acid and about 5˜1 vol. % of hydrofluoric acid, and gradually decreasing HF concentration in the etching process) is used to remove part of the second metal layer 380 and part of the oxide layer 370. The different HF concentration causes different etching rates between Ti and SiO₂ (the etching rate of SiO₂ is greater than that of Ti). Thus, a cavity is formed at either side of the gate dielectric layer 382. The cavity can decrease gate leakage.

In FIG. 3E, using the photoresist pattern 390 as a mask, a heavy doping ion implantation 400 such as n⁺-type ions implantation is performed on the semiconductor island 360 to form a self-aligned source/drain region 410 in part of the semiconductor island 360.

In FIG. 3F, the photoresist pattern 390 is then removed. Using the gate 381 as a mask, a light doping ion implantation 420, such as n—type ions implantation, is performed on the semiconductor island 360 to form a self-aligned lightly doped drain (LDD) region 430 in part of the semiconductor island 360. According to the present invention, a TFT structure and a capacitor structure are obtained.

In FIG. 3G, a transparent conducting layer (not shown) such as indium tin oxide (ITO) or indium zinc oxide (IZO), is formed on the TFT structure, the color filter 340 and the first metal layer 330. A photolithography procedure using a fourth reticle is then performed, and part of the transparent conducting layer (not shown) is removed to form a transparent electrode pattern 440 on the color filter 340. The transparent electrode pattern 440 also electrically connects the source/drain region 410 and the first metal layer 330. According to the present invention, a TFT structure having an LDD is formed on the color filter with only four photolithography processes.

In FIG. 3G, a passivation layer 450 is formed on the TFT structure and the capacitor structure. The passivation layer 450 can be transparent organic material.

It should be noted that the first metal layer 330 and the gate 381 can serve as black matrix for shading light, and the layout of the first metal layer 330 can be any shape. Thus, the present method can allow the color filter and the black matrix to be simultaneously formed on the TFT array substrate.

Moreover, known in the conventional LCD process, a first orientation film (not shown) is formed on the passivation layer 450. A transparent insulating substrate (upper substrate, not shown) opposite the substrate 300 is provided. A common electrode (not shown) is formed on the inner side of the upper substrate, and then a second orientation film (not shown) is formed on the common electrode. Then, liquid crystal material is filled into the space between the two substrates to form a liquid crystal layer (not shown). Thus, an LCD device is obtained.

As mentioned above, according to the present invention, the following effects can be obtained.

(1) The present invention uses the etching rate difference between metal and oxide, and self-aligned implantation. Thus, a TFT structure having an LDD can be obtained with only two photolithography processes, thereby simplifying manufacturing process, and decreasing consumption of reticles and manufacturing cost. Moreover, a cavity can be formed at either side of the gate dielectric layer, thereby reducing gate leakage.

(2) The present invention uses the etching rate difference between metal and oxide, and self-aligned implantation. Thus, a TFT structure having a LDD can be formed on a color filter with only four photolithography processes, thereby simplifying the manufacturing process, and decreasing a consumption of reticles and manufacturing costs.

(3) According to the present invention, the color filter 340 adjoins the transparent electrode 440, thereby solving the coupling capacitance issue.

(4) According to the present invention, the first metal layer 330 can serve as a black matrix without additional fabrication, thereby simplifying the manufacturing process, and decreasing manufacturing costs.

Finally, while the invention has been described by way of example and in terms of the above, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming a thin film transistor device, comprising the steps of:
providing a substrate;
using a first reticle and forming a semiconductor island on the substrate;
forming an oxide layer on the semiconductor island;
forming a metal layer on the oxide layer;
using a second reticle and forming a photoresist pattern on part of the metal layer;
using the photoresist pattern as a mask and isotropically etching part of the metal layer and part of the oxide layer to form a gate and a gate dielectric layer, wherein the photoresist pattern is wider than the gate and gate dielectric layer, but narrower than the semiconductor island;
using the photoresist pattern as a mask and performing a heavy doping ion implantation on the semiconductor island to form a source/drain region in part of the semiconductor island;
removing the photoresist pattern; and
using the gate as a mask and performing a light doping ion implantation on the semiconductor island to form a lightly doped drain (LDD) region in part of the semiconductor island.

2. The method according to claim 1, wherein the substrate is a glass substrate.

3. The method according to claim 1, wherein the semiconductor island is a polysilicon layer.

4. The method according to claim 1, wherein the oxide layer is a SiO₂ layer.

5. The method according to claim 1, wherein the metal layer is an Al, Ti, Ta, Cr, Mo, MoW or alloy of the above layer.

6. The method according to claim 1, wherein the method of isotropically etching part of the metal layer and the oxide layer comprises:
using a first etchant with a first etching rate to remove part of the metal layer; and
using a second etchant with a second etching rate to remove part of the oxide layer;
wherein the second etching rate is greater than the first etching rate in order to make the width of the gate dielectric layer smaller than the width of the gate.

7. The method according to claim 6, wherein the metal layer is an Al or Ti layer.

8. The method according to claim 7, wherein the oxide layer is a SiO₂ layer.

9. The method according to claim 8, wherein the first etchant comprises phosphoric acid, acetic acid and nitric acid.

10. The method according to claim 8, wherein the second etchant comprises hydrofluoric acid.

11. A method of forming a thin film transistor device on a color filter, comprising the steps of:
providing a substrate having a light-transmitting area and a capacitor area, where in the light-transmitting area further includes an active area;
forming a first metal layer on the substrate;
using a first reticle and removing part of the first metal layer to form a hole exposing the substrate in the light-transmitting area, wherein the first metal layer in the capacitor area serves as a lower electrode of a capacitor;
filling a pigment into the hole to form a color filter on the substrate;
forming a first buffer layer on the color filter and the metal layer;
using a second reticle and forming a semiconductor island on the first buffer layer in the active area;
forming an oxide layer on the semiconductor island;
forming a second metal layer on the oxide layer;
using a third reticle and forming a photoresist pattern on part of the second metal layer;
using the photoresist pattern as a mask and isotropically etching part of the second metal layer, part of the oxide layer and part of the first buffer layer to expose part of the color filter and part of the first metal layer and thus forming agate, agate dielectric layer, an upper electrode of the capacitor and a dielectric layer of the capacitor, wherein the photoresist pattern is wider than the gate and the gate dielectric layer, but narrower than the semiconductor island;
using the photoresist pattern as a mask and performing a heavy doping ion implantation on the semiconductor island to form a source/drain region in part of the semiconductor island;
removing the photoresist pattern;
using the gate as a mask and performing a light doping ion implantation on the semiconductor island to form a lightly doped drain (LDD) region in part of the semiconductor island; and
using a fourth reticle and forming a transparent conducting layer on the color filter, wherein the transparent conducting layer electrically connects the source/drain region and the first metal layer.

12. The method according to claim 11, further comprising:
forming a second buffer layer between the first metal layer and the substrate.

13. The method according to claim 11, wherein the first buffer layer is a SiO₂ layer.

14. The method according to claim 12, wherein the second buffer layer is a SiO₂ layer.

15. The method according to claim 11, wherein the semiconductor island is a polysilicon layer.

16. The method according to claim 11, wherein the second metal layer is an Al, Ti, Ta, Cr, Mo, MoW or alloy of the above layer.

17. The method according to claim 11, wherein the method of isotropically etching part of the second metal layer and part of the oxide layer comprises:
using a first etchant with a first etching rate to remove part of the second metal layer; and
using a second etchant with a second etching rate to remove part of the oxide layer;
wherein the second etching rate is greater than the first etching rate in order to form the width of the gate dielectric layer smaller than the width of the gate.

18. The method according to claim 17, wherein the second metal layer is an Al or Ti layer.

19. The method according to claim 18, wherein the oxide layer is a SiO₂ layer.

20. The method according to claim 19, wherein the first etchant comprises phosphoric acid, acetic acid and nitric acid.

21. The method according to claim 19, wherein the second etchant comprises hydrofluoric acid.

22. The method according to claim 11, wherein the pigment is red, green or blue.

23. The method according to claim 11, wherein the transparent conducting layer is an indium tin oxide (ITO) or indium zinc oxide (IZO) layer.
